(19) United States
(12) Patent Application Publication
(10) Pub. No.: US 2009/0209079 A1
(43) Pub. Date: Aug. 20, 2009

(54) METHOD FOR MANUFACTURING SEMICONDUCTOR DEVICE

(75) Inventors: Kiyonori OYU, Chuo-ku (JP); Kensuke Okonogi, Chuo-ku (JP); Akio Shima, Hino-shi (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/356,843

(22) Filed: Jan. 21, 2009

(30) Foreign Application Priority Data
Jan. 22, 2008 (JP) 2008-011387

(51) Int. Cl. H01L 21/265; H01L 21/268

(52) U.S. Cl. 438/306; 438/542; 257/E21.347; 257/E21.335

(57) ABSTRACT

A method for manufacturing a semiconductor device includes forming a diffusion layer on a silicon substrate by doping an impurity of a first conductivity type into a region of a second conductivity type opposite to the first conductivity type and performing a heat treatment; implanting nitrogen or fluorine ions into the diffusion layer; and irradiating carbon dioxide gas laser light to the diffusion layer after the implanting.

### BACKGROUND OF THE INVENTION

1. Field of the Invention

The present invention relates to a method for manufacturing a semiconductor device and, more particularly, to a method for manufacturing a semiconductor device whereby it is possible to reduce the leakage current of a pn junction formed in a silicon substrate including a diffusion layer.

2. Description of Related Art

In the manufacture of a regular MOS transistor using a silicon substrate, a well layer of a first conductivity type the same as the conductivity type of a region to serve as a channel is formed in a region surrounded by an element-isolating region, and then a gate insulating film and a gate electrode are formed. After that, ion implantation and heat treatment are performed to form a diffusion layer of a second conductivity type to serve as a source/drain.

In the MOS transistor formed in this way, it is a crucial issue to reduce the leakage current of a pn junction.

In order to reduce the reverse leakage current of a pn junction composed Of a source/drain diffusion layer and a well layer, Japanese Patent Laid-Open No. 2005-197547 (Patent Document 1) describes a method in which a specific dose amount (1×10¹³ to 3×10¹³/cm²) of phosphorous is implanted, and then a heat treatment is performed to form a source/drain diffusion layer. After that, a halogen element is implanted under conditions in which the implantation is limited to a specific dose amount (smaller than the above-described dose amount of phosphorous) and to a specific implantation depth (shallower than the implantation depth of the above-described diffusion layer). Then, a heat treatment is performed for 1 to 60 seconds at 900 to 1000° C.

Although FIG. 6 of Patent Document 1 shows an effect of reduction in the junction leakage current by the method described therein, there is a demand for an even greater effect of reduction.

In addition, the method described in Patent Document 1 is only applicable to the formation of low-concentration diffusion layers, since the dose amount of ions used to form a diffusion layer is small. Thus, the method has not been able to reduce a junction leakage current when forming high-concentration diffusion layers.

### SUMMARY

In one embodiment, there is provided a method for manufacturing a semiconductor device, including:

forming a diffusion layer on a silicon substrate by doping an impurity of a first conductivity type into a region of a second conductivity type opposite to the first conductivity type and performing a heat treatment;

implanting nitrogen or fluorine ions into the diffusion layer; and

irradiating carbon dioxide gas laser light to the diffusion layer after the implanting.

In another embodiment, there is provided a method for manufacturing a semiconductor device including a MOS transistor, including:

forming a gate electrode on a silicon substrate through a gate insulating film;

doping the silicon substrate with an impurity and performing a heat treatment, thereby forming a diffusion layer to serve as a source/drain on both sides of the gate electrode;

performing an ion-implanting of nitrogen or fluorine into the diffusion layer; and

irradiating carbon dioxide gas laser light to the diffusion layer after the ion-implantation.

In another embodiment, there is provided a method of manufacturing a semiconductor device, including:

forming a first region having a first conductivity type in a semiconductor substrate;

forming a second region having a second conductivity type coupled to the first region;

implanting a predetermined ion into the second region; and

irradiating a laser light having a energy absorbed at bonds between silicon and oxygen atoms to the second region.

According to an embodiment, it is possible to manufacture a semiconductor device that has reduced junction leakage current without being constrained by the concentration of a diffusion layer.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic view used to explain a manufacturing method according to an exemplary embodiment of the present invention;

FIG. 2 is a schematic view used to explain one step of the manufacturing method according to the exemplary embodiment of the present invention;

FIG. 3 is a schematic view used to explain a step following the manufacturing step illustrated in FIG. 2;

FIG. 4 is a schematic view used to explain a step following the manufacturing step illustrated in FIG. 3;

FIG. 5 is a schematic view used to explain a step following the manufacturing step illustrated in FIG. 4;

FIG. 6 is a schematic view used to explain irradiation with a carbon dioxide gas laser in the manufacturing step illustrated in FIG. 5;

FIG. 7 is a schematic view used to explain a step following the manufacturing step illustrated in FIG. 5;

FIG. 8 is a graphical view used to explain effects of reduction in a junction leakage current in the case of fluorine implantation;

FIG. 9 is another graphical view used to explain effects of reduction in the junction leakage current in the case of fluorine implantation;

FIG. 10 is a graphical view showing a fluorine concentration distribution of a diffusion layer in the depth direction thereof in an exemplary embodiment of the present invention;

FIG. 11 is a graphical view used to explain effects of reduction in a junction leakage current in the case of nitrogen implantation;

FIG. 12 is another graphical view used to explain effects of reduction in the junction leakage current in the case of nitrogen implantation; and

FIG. 13 is a graphical view showing a nitrogen concentration distribution of a diffusion layer in the depth direction thereof in an exemplary embodiment of the present invention.

### DETAILED DESCRIPTION OF THE PREFERRED EMBODIMENTS

In a manufacturing method according to one exemplary embodiment of the present invention, a diffusion layer is formed so that a pn junction is formed in a silicon substrate. Then, nitrogen or fluorine is ion-implanted into this diffusion layer. After that, this diffusion layer is irradiated with a carbon dioxide gas laser.

This diffusion layer is formed by doping the silicon substrate with an impurity and performing a heat treatment. This heat treatment can be performed in the same way as a regular heat treatment used to electrically activate impurities. Heat treatment temperature can be set to 800 to 1100° C. from the viewpoint of an activation rate, a thermal diffusion range, and the like. Impurity doping is preferably performed with an oxide film formed on the silicon substrate. With the oxide film, it is possible to block contaminants which may otherwise adhere to a substrate surface at the time of impurity doping. Thus, it is possible to suppress a leakage current attributable to the contaminants.

The dose amount of nitrogen or fluorine is preferably within the range from 5×10¹²/cm² to 1×10¹⁴/cm² and, more preferably, within the range from 1×10¹³/cm² to 5×10¹³/cm².

The conditions of carbon dioxide gas laser irradiation are preferably set so as to satisfy the below-described conditions. At that time, the temperature of the silicon substrate and the amount of laser absorption at the silicon substrate are preferably set so that the silicon substrate does not melt down.

Carbon dioxide gas laser irradiation can be performed with the silicon substrate set to room temperature or placed under heating.

When irradiating laser light under room temperature or relatively low temperatures, the absorbed amount of carbon dioxide gas laser light is small. Therefore, it is necessary to increase laser output to make the absorbed amount of the laser larger. By raising the temperature of the silicon substrate, it is possible to increase the amount of carbon dioxide gas laser light absorbed at the silicon substrate. Accordingly, from the viewpoint of achieving an even greater effect of laser irradiation, it is preferable to perform laser irradiation with the silicon substrate heated to 300° C. or higher, more preferably, 350° C. or higher and, even more preferably, 400° C. or higher. If the substrate temperature is too high, unwanted thermal oxidation progresses or the amount of laser absorption becomes larger in an atmosphere containing an oxidizing gas, such as air, thus causing the substrate surface to roughen or the substrate to melt down. Accordingly, the substrate temperature is preferably set to 500° C. or lower and, more preferably, 450° C. or lower. By setting the substrate temperature within such a range as described above, it is possible to suppress laser output and have carbon dioxide gas laser light efficiently absorbed. Thus, it is possible to perform excellent laser irradiation less susceptible to atmospheric effects.

The atmosphere at the time of laser irradiation may be air under normal pressure or an inert gas atmosphere, such as nitrogen, and is thus not limited in particular.

The amount of laser light that the silicon substrate absorbs (hereinafter referred to as the “amount of laser absorption”) at the time of carbon dioxide gas laser irradiation can be set within the range from 1000 to 6000 W/mm², more preferably, within the range from 2000 to 4000 W/mm² and, even more preferably, within the range from 3000 to 4000 W/mm². Accordingly, from the viewpoint of achieving a sufficient irradiation effect, this amount of laser absorption is preferably 1000 W/mm² or larger and, more preferably, 2000 W/mm² or larger. If the amount of laser absorption is too large, the roughening of a laser-irradiated surface or the meltdown of the silicon substrate may occur. Accordingly, the amount of laser absorption is preferably 6000 W/mm² or smaller and, more preferably, 4000 W/mm² or smaller. Note that the amount of laser absorption is given by a product of laser output and absorptance determined by measuring the reflectance of laser light.

The area of laser irradiation can preferably be, for example, 3 to 10 mm in the long side thereof and 50 to 200 μm in the short side thereof. More preferably, the short side can be 100 to 200 μm and, even more preferably, 100 to 150 μm. The rate of laser scanning can be set within the range, for example, from 5 to 10 cm/s. The shape of the laser-irradiated area and the scanning rate can be selected according to throughputs (<10 minutes/300 mm wafer) tolerable to laser irradiation treatment. Laser scanning is preferably performed by means of raster scan, so that a half of each long side overlaps with each other.

According to the above-described manufacturing method, the following advantages can be obtained.

By ion-implanting nitrogen or fluorine into the diffusion layer formed in the silicon substrate and irradiating with the carbon dioxide gas laser, it is possible to realize a junction leakage current one-tenth the junction leakage current of a case in which this ion-implantation and laser irradiation are not performed.

In a case in which ion-implantation is performed on the above-described diffusion layer but no laser irradiation is performed thereon, the junction leakage current can only be reduced to one-third. Alternatively, in a case in which no ion-implantation is performed on the above-described diffusion layer but laser irradiation is performed thereon, the junction leakage current is not reduced. Hence, a sufficient effect of reduction in the junction leakage current is available only when the ion-implantation of nitrogen or fluorine and the irradiation of carbon dioxide gas laser light are performed in combination.

The reason for being able to obtain the above-described advantages will be described hereinbelow.

The inventor of the present invention et al. have revealed that the main cause of junction leakage current is generation and recombination due to the dangling bonds of Si and that the forms of the dangling bonds of Si are classified into those present in a boundary face between a silicon dioxide film and a silicon substrate and those present in crystal defects composed of holes and oxygen in the silicon substrate. That is, the dangling bonds of Si tend to occur in a portion where bonds of silicon and oxygen atoms exist.

The energy of carbon dioxide gas laser light is absorbed at bonds between silicon and oxygen atoms because of the wavelength of the laser light. As a result, the above-described bonds break up and the silicon and oxygen atoms remain in a separated state while the carbon dioxide gas laser light is being irradiated. If a nitrogen or fluorine atom exists in the vicinity of the silicon atom under laser irradiation, the silicon atom combines with the nitrogen or fluorine atom. Even after laser irradiation, the silicon atom and the nitrogen or fluorine atom remain in a bonded state since the bond strength between the silicon atom and the nitrogen or fluorine atom is strong.

For example, if a crystal defect is composed of two holes (a state in which two Si atoms are absent) and two oxygen atoms, there exist two dangling bonds of Si. Here, if the two oxygen atoms are substituted with two nitrogen atoms, then the dangling bonds of Si can no longer exist. Likewise, if the two oxygen atoms are substituted with, for example, six fluorine atoms, then the dangling bonds of Si can no longer exist either. Accordingly, the original number of bonds between silicon and oxygen atoms decreases and, consequently, it is possible to prevent dangling bonds of Si from being generated.

In order to allow silicon atoms and nitrogen or fluorine atoms to efficiently combine with each other as described above, a large number of nitrogen or fluorine atoms needs to exist near a boundary face between the above-described silicon dioxide film and the silicon substrate and near crystal defects composed of holes and oxygen in the silicon substrate.

In laser irradiation under the above-described conditions, nitrogen or fluorine atoms introduced by implantation hardly move. Therefore, these atoms can exist in a large number in the peripheries of the above-described boundary face and crystal defects.

Accordingly, it is possible to efficiently decrease the number of dangling bonds of Si existent before the implantation of nitrogen or fluorine. Thus, it is possible to effectively reduce the junction leakage current.

In the method of Patent Document 1 based on fluorine implantation and heat treatment, the efficiency of breaking up bonds of silicon and oxygen atoms by heat treatment is extremely low, compared with break-up efficiency based on carbon dioxide gas laser irradiation. In addition, fluorine diffuses due to heat treatment and, therefore, a fluorine concentration in the periphery of the above-described boundary face and crystal defects becomes lower. Thus, it is not possible to efficiently decrease the number of dangling bonds of Si. Even if possible, the number can only be decreased to one-third at the best.

In the present exemplary embodiment, a diffusion layer is formed by ion implantation and heat treatment. Then, the ion implantation of nitrogen or fluorine is performed on the diffusion layer in which crystal defects composed of holes and oxygen have been formed. Then, carbon dioxide gas laser light is irradiated while allowing nitrogen or fluorine to exist in the periphery of these crystal defects. Consequently, it is possible to efficiently substitute bonds of silicon and oxygen atoms with bonds of silicon and nitrogen (or fluorine) atoms. Thus, it is possible to efficiently decrease the number of dangling bonds.

No other types of laser irradiation than carbon dioxide gas laser irradiation can efficiently break up bonds of silicon and oxygen atoms. In any other types of laser irradiation, bonds of silicon and oxygen atoms can be broken up, if possible at all, only by means of heat generation caused by laser irradiation. Thus, there is obtained only an effect equal to or less than that of the method based on fluorine implantation and heat treatment described in Patent Document 1.

In addition, if a heat treatment for the purpose of forming a diffusion layer is not performed following ion implantation for that purpose, it is difficult to remedy all of crystal defects generated by ion implantation for diffusion layer formation, even if nitrogen or fluorine implantation and carbon dioxide gas laser irradiation are performed. Accordingly, the junction leakage current increases to the contrary if the crystal defects cannot be remedied. If a heat treatment is performed following nitrogen or fluorine implantation, in an attempt to remedy the above-described crystal defects, nitrogen or fluorine diffuses. Thus, it is not possible to obtain a desired effect.

### Examples

Hereinafter, a further description will be made by referring to exemplary embodiments.

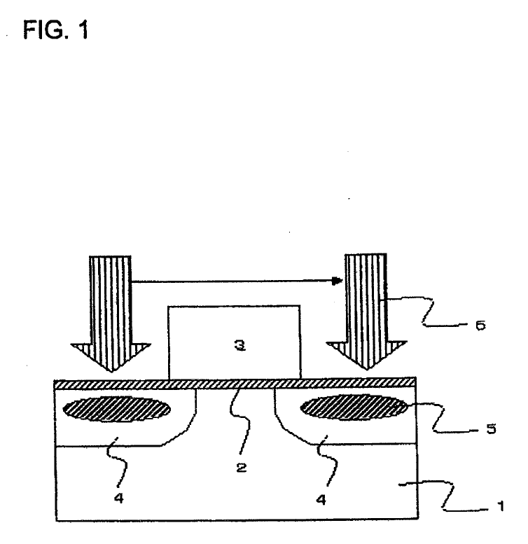

As one exemplary embodiment, the present invention can be applied to the formation of a MOS transistor, as illustrated in FIG. 1. A gate electrode 3 is formed on a surface of a silicon substrate 1 through a gate oxide film 2, an impurity is ion-implanted, and a heat treatment is performed, thereby forming a diffusion layer 4. After that, the ion implantation of nitrogen or fluorine is performed on this diffusion layer 4 (reference numeral 5 in the figure denotes a region in which nitrogen or fluorine is implanted). Next, this diffusion layer is irradiated with a carbon dioxide gas laser 6.

The above-described manufacturing method can be carried out specifically in the below-described manner.

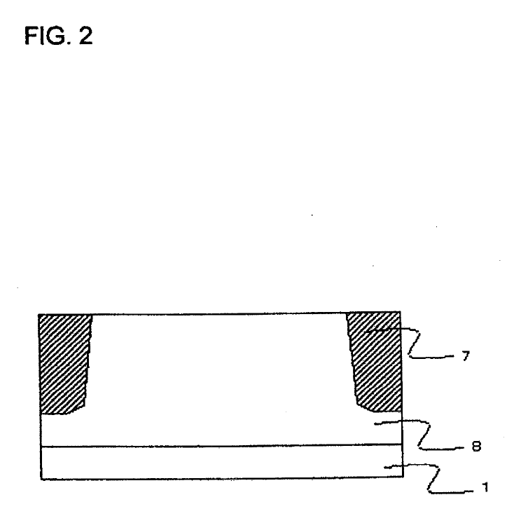

As illustrated in FIG. 2, a shallow-trench element-isolating region 7 and a p-type well layer 8 were formed on the principal surface of the silicon substrate 1. The shallow-trench element-isolating region 7 was formed by forming a trench by processing the silicon substrate by etching, and then filling the trench with a silicon dioxide film. A p-type well layer 8 was formed by implanting boron in a multistage manner, so that a predetermined concentration was reached at a predetermined depth, and then applying an N₂, 1000° C., 10 second-heat treatment. Note that the boron concentration of a portion for forming the channel of a MOS transistor was set to approximately 3×10¹⁷/cm³.

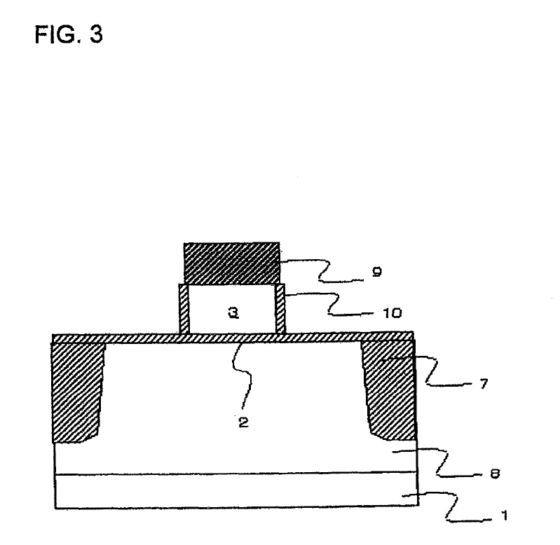

Next, as illustrated in FIG. 3, the gate insulating film 2 and the gate electrode 3 were formed As the gate insulating film 2, a 5 nm-thick silicon dioxide film was formed by thermal oxidation. The gate electrode 3 was formed by processing a polysilicon film by etching using a cap insulating layer 9 as a mask. Here, the cap insulating layer 9 was formed of a 200 nm-thick silicon nitride film. In addition, as a polysilicon film 3, there was formed a 200 nm-thick film into which phosphorous of 1×10²⁰/cm³ in concentration had been introduced. Note that after forming the gate electrode 3, a silicon dioxide film 10 was formed on the side surface of a gate by thermal oxidation to a thickness of 5 nm.

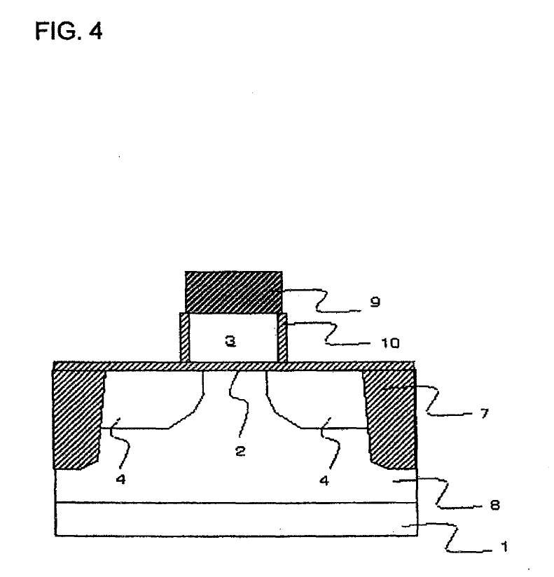

Next, as illustrated in FIG. 4, an impurity was ion-implanted, and then an RTA (Rapid Thermal Anneal) was performed to form the diffusion layer 4 to serve as a source/drain. Ion implantation conditions were set as “impurity: phosphorous, acceleration energy: 50 keV, dose amount: 1×10¹⁴/cm².” The conditions of heat treatment after ion implantation were set as “N₂, 1000° C., 10 seconds.”

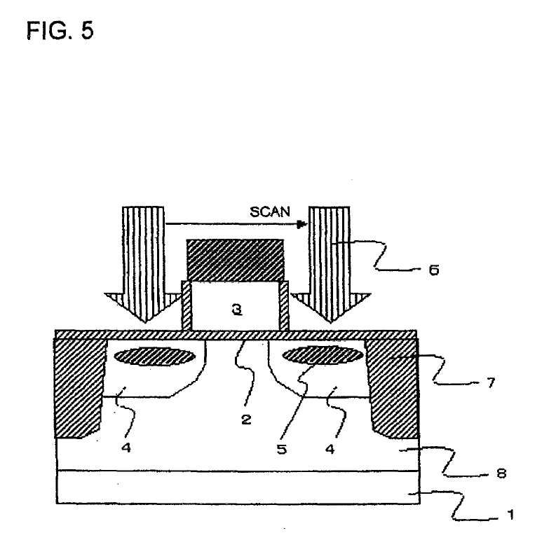

After that, as illustrated in FIG. 5, fluorine was ion-implanted into the diffusion layer 4, and then the diffusion layer 4 was irradiated with the carbon dioxide gas laser 6. The ion implantation of fluorine (hereinafter referred to as “fluorine implantation”) was performed at 10 keV with a dose amount ranging from 5×10¹²/cm² to 1×10¹⁴/cm².

Note that for comparison, there were also fabricated, as conventional examples, a sample in which only laser irradiation was performed without performing fluorine implantation and a sample in which neither fluorine implantation nor carbon dioxide gas laser irradiation was performed.

Here, the temperature of the silicon substrate when irradiating carbon dioxide gas laser light was set to 300 to 500° C. The silicon substrate was heated by resistively heating a stage on which the silicon substrate was mounted. Note that the above-mentioned temperature is the temperature of the stage.

The area of laser irradiation was set as 5 mm in the long side thereof and 100 μm in the short side thereof. The samples were scanned at a rate of 8 cm/s. In addition, the amount of laser absorption was set within the range from 1500 to 6000 W/mm². Note that the upper limit of the amount of laser absorption was determined by taking into consideration the service life of the laser.

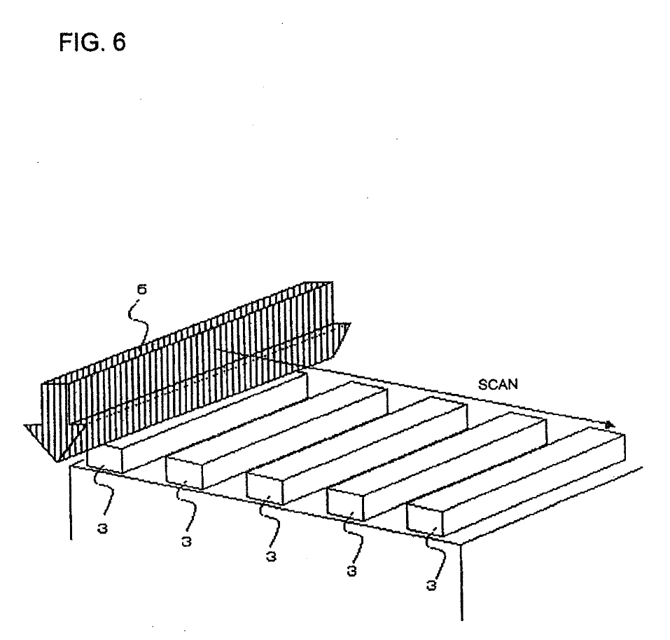

Laser irradiation was performed so that no shadows were made by the gate electrode and the diffusion layer was thereby irradiated efficiently, as illustrated in FIG. 6. Laser scanning was performed by means of raster scan, so that a half of each long side overlapped with each other.

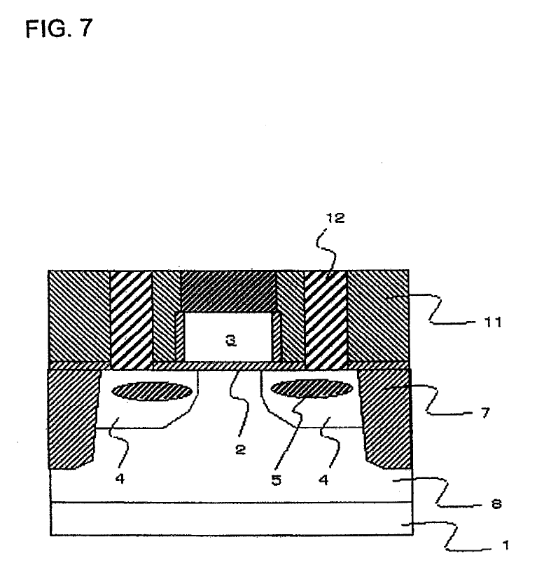

Next, as illustrated in FIG. 7, an interlayer insulating film 11 was formed so as to cover the gate electrode. After that, a source/drain electrode 12 was formed to obtain a MOS transistor.

Note that an approximately 1000° C., 10-second heat treatment was performed in the formation of the source/drain electrode 12 following the above-described laser irradiation, in order to reduce electrode resistance. The below-described advantages obtained in the present example remained the same when this heat treatment for reducing electrode resistance was performed within the temperature range from 800° C. to 1050° C. and within the time range from 1 second to 30 seconds.

Hereinafter, the advantages provided by the present example will be described.

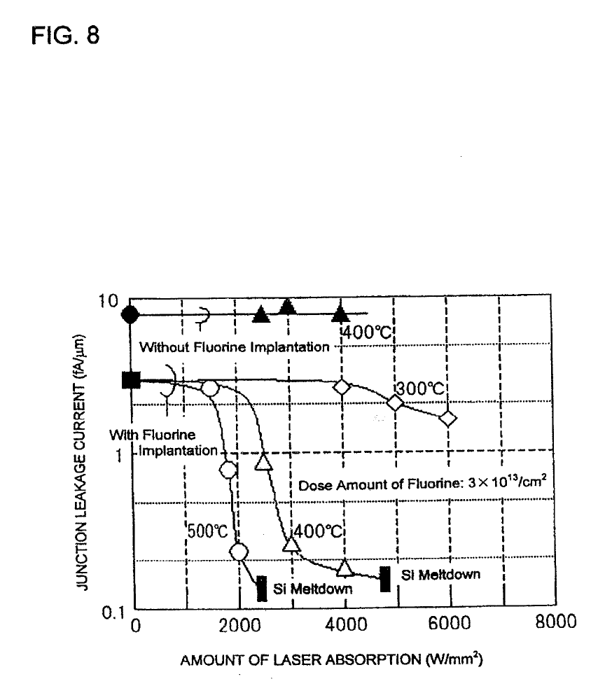

FIG. 8 shows a relationship between a junction leakage current and the amount of laser absorption. For the junction leakage current, there was used, as an index, a junction leakage current at an end of the gate electrode which governed the junction leakage current of a miniaturized MOS transistor. This figure summarizes the results in which the temperature of the silicon substrate differed at the time of laser irradiation and the results in which fluorine implantation was performed (dose amounts 3×10¹³/cm²) and not performed.

If neither fluorine implantation nor laser irradiation is performed (denoted by “” in the figure as conventional example 1), then the junction leakage current is 8.5 fA/μm.

If fluorine implantation is not performed but laser irradiation is performed (denoted by “▴” in the figure), then the junction leakage current is the same as that of conventional example 1. From these results, it is understood that the junction leakage current cannot be reduced simply by irradiating carbon dioxide gas laser light.

If fluorine implantation is performed but laser irradiation not performed (denoted by “▪” in the figure as conventional example 2, which corresponds to the method of Patent Document 1), then the junction leakage current is 3 fA/μm. This means that the junction leakage current has been reduced to approximately one-third, compared with conventional example 1.

If both fluorine implantation and laser irradiation are performed (denoted by “⋄”, “Δ”, and “◯” in the figure), which is an exemplary embodiment of the present invention, then the junction leakage current reduced, though this depended on the silicon substrate temperature (which is shown in the figure).

If the substrate temperature is 300° C. (denoted by “⋄” in the figure), then the junction leakage current decreases in a region where the amount of laser absorption is large. From this result, it is understood that the substrate temperature is preferably 300° C. or higher.

If the substrate temperature is 400° C. (denoted by “Δ” in the figure), then the junction leakage current decreases as the amount of laser absorption increases. The junction leakage current drops drastically when the amount of laser absorption is in the vicinity of 2500 W/mm², and is reduced most when the amount of laser absorption is within the range from 3000 to 4000 W/mm² (0.2 to 0.3 fA/μm). According to the present example, the junction leakage current is reduced to approximately one-thirtieth or less, compared with conventional example 1, and to one-tenth or less, compared with conventional example 2. Note that if the amount of laser absorption increases further, the silicon substrate melts down.

If the substrate temperature is 500° C. (denoted by “◯” in the figure), then the junction leakage current drops drastically when the amount of laser absorption is in the vicinity of 2000 W/mm², and the silicon substrate melts down when the amount of laser absorption slightly exceeds 2000 W/mm².

The junction leakage current can be reduced at a smaller amount of laser absorption by raising the substrate temperature. As a result, however, it is understood that the dependence of the effect of reduction in the junction leakage current upon the amount of laser absorption increases. Consequently, it becomes difficult to control the junction leakage current. For example, if the absorptance of laser light changes depending on the state of a surface being irradiated, the effect of reduction varies significantly. This variation can cause the silicon substrate to melt down. In a case where the state of the surface being irradiated is stable, the substrate temperature may be higher than 500° C. From the viewpoint of controllability, however, it is preferable that the substrate temperature is not higher than 500° C.

From the results described above, the temperature of the silicon substrate is preferably within the range from 300 to 500° C. and the amount of laser absorption is preferably within the range from 2000 to 6000 W/mm². The amount of laser absorption is preferably 4000 W/mm² or smaller, however, if the prevention of the silicon substrate from meltdown is taken into consideration. From the viewpoint of effectively reducing the junction leakage current, the amount of laser absorption is preferably 3000 W/mm² or larger.

Note that the temperature of the silicon substrate and the amount of laser absorption described above are specified with respect to the surface structure of the substrate used in the present example (FIG. 5). If the structure of a surface being laser-irradiated is different from that of the present example, the relationships between the silicon substrate temperature and the amount of laser absorption and between the silicon substrate temperature and the junction leakage current may more or less vary. If condition setting is carried out as appropriate, according to the above-described results, it is possible to obtain sufficient advantages according to the present invention. Furthermore, even though an amount of laser absorption of 6000 W/mm² is exceeded, it is still possible to obtain the advantages according to the present invention, on condition that there is no problem with the service life of the laser and that the silicon substrate does not melt down.

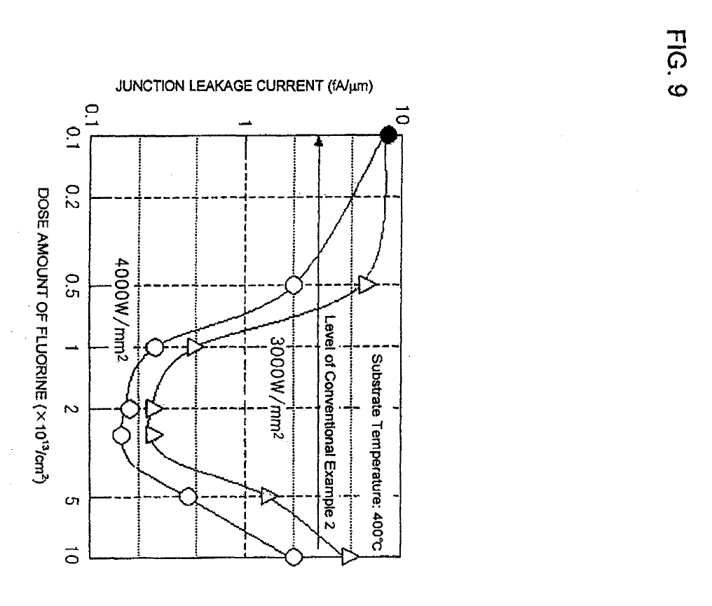

FIG. 9 shows a relationship between the junction leakage current and the dose amount of fluorine. This figure shows the result when the silicon substrate temperature is 400° C. and the amount of laser absorption is 3000 W/mm² and 4000 W/mm².

If the amount of laser absorption is 3000 W/mm² (denoted by “Δ” in the figure), then the junction leakage current is reduced drastically when the dose amount is between 5×10¹² and 1×10¹³/cm². The junction leakage current is reduced more than in conventional example 2 when the dose amount is between 1×10¹³ and 5×10¹³/cm². The effect of reduction is greatest in the vicinity of 2×10¹³ to 3×10¹³/cm² (approximately one-thirtieth the value denoted by “”, which corresponds to conventional example 1). The junction leakage current gradually increases as the dose amount becomes larger than the above-described values and the effect of reduction disappears when the dose amount exceeds approximately 1×10¹⁴/cm². If the amount of laser absorption is 4000 W/mm² (denoted by “◯” in the figure), then the junction leakage current is reduced more than in conventional example 2 when the dose amount is between 5×10¹² and 1×10¹⁴/cm². The junction leakage current is reduced further when the dose amount is between 1×10¹³ and 5×10¹³/cm², and the effect of reduction is greatest in the vicinity of 2×10¹³ to 3×10¹²/cm². From the results described above, it is understood that the dose amount of fluorine in the present example is preferably in the range from 5×10¹²/cm² to 1×10¹⁴/cm² and, more preferably, in the range from 1×10¹³/cm² to 5×10¹³/cm².

As described above, in the example of the present invention in which both the above-described fluorine implantation and carbon dioxide gas laser irradiation were applied, it was possible to reduce the junction leakage current to approximately one-thirtieth the junction leakage current of conventional example 1 in which neither fluorine implantation nor laser irradiation was performed. As a result, it was possible to reduce a stand-by current governed by the junction leakage current. Consequently, it was possible to realize the low power consumption of a semiconductor device in which MOS transistors were integrated.

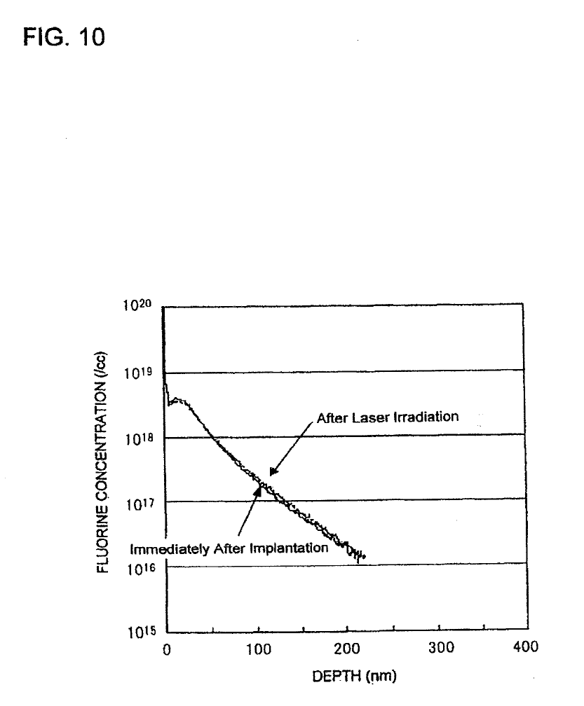

The measurement of the concentration distribution of fluorine implanted into the above-described diffusion layer showed that as illustrated in FIG. 10, the fluorine concentration distribution in the depth direction of the diffusion layer hardly changed before and after laser irradiation under the laser irradiation conditions of the above-described example. That is, in the case of carbon dioxide gas laser irradiation in the present invention, the diffusion of fluorine within the diffusion layer is almost negligible.

Next, a description will be made of an example in which manufacturing was carried out in the same way as in the above-described example, except that the ion implantation of nitrogen (hereinafter referred to as “nitrogen implantation”) was performed in place of the above-described fluorine implantation.

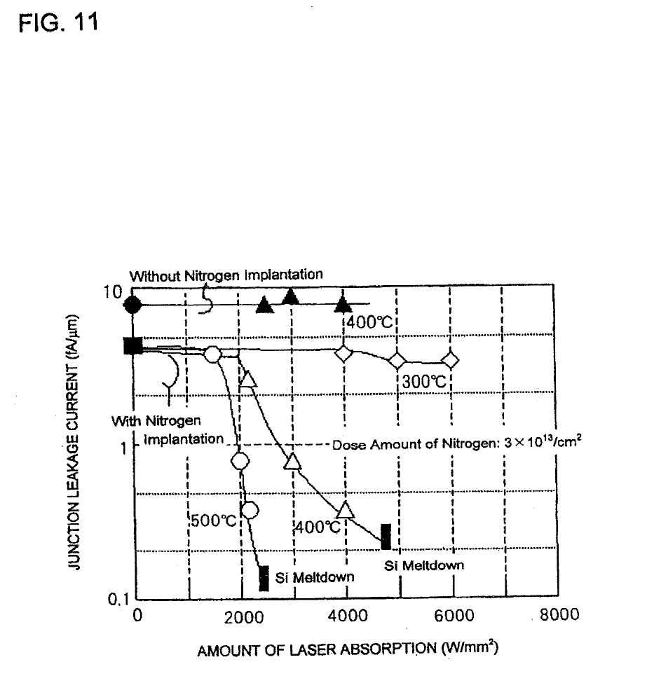

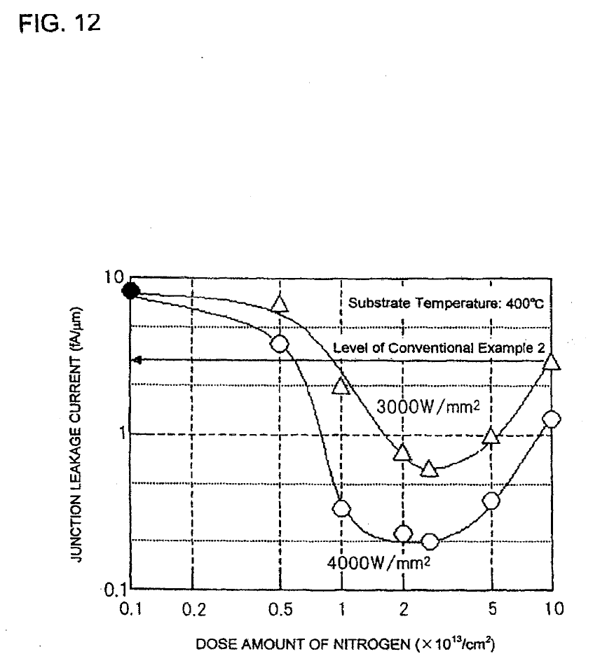

FIG. 11 shows a relationship between a junction leakage current and the amount of laser absorption, and FIG. 12 shows a relationship between the junction leakage current and the dose amount of nitrogen. Also in the case of nitrogen implantation, there has been obtained an excellent effect of reduction in the junction leakage current.

Also in the case of nitrogen implantation, like in the case of fluorine implantation, the temperature of the silicon substrate is preferably within the range from 300 to 500° C. and the amount of laser absorption is preferably within the range from 2000 to 6000 W/mm². When the prevention of the silicon substrate from meltdown is taken into consideration, the amount of laser absorption is preferably 4000 W/mm² or smaller. From the viewpoint of effectively reducing the junction leakage current, the amount of laser absorption is preferably 3000 W/mm² or larger. The dose amount of nitrogen is preferably in the range from 5×10¹²/cm² to 1×10¹⁴/cm² and, more preferably, in the range from 1×10¹³/cm² to 5×10¹³/cm².

As shown in FIGS. 8 and 9 and in FIGS. 11 and 12, the effect of reduction in the junction leakage current due to fluorine implantation is greater, compared with the effect of reduction due to nitrogen implantation. The reason for this is probably that fluorine is a monovalent ion and has high electronegativity, whereas nitrogen is a trivalent ion, and therefore the ratio of bonding between fluorine and the dangling bonds of silicon is higher than the ratio of bonding between nitrogen and the dangling bonds of silicon.

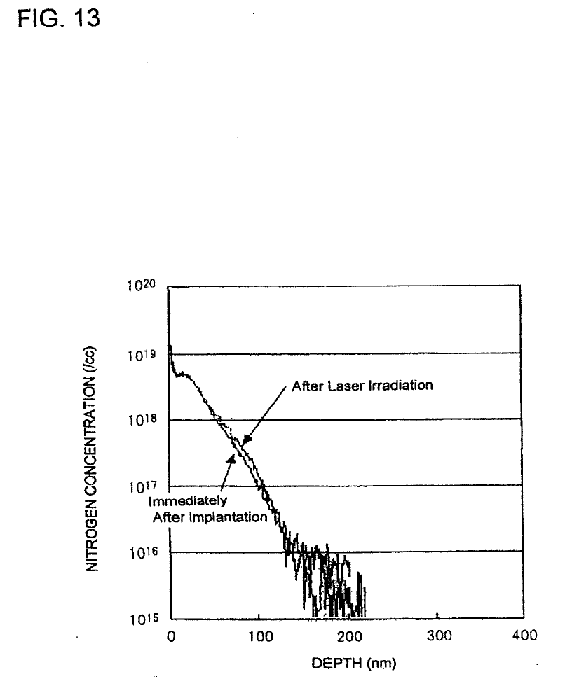

The measurement of the concentration distribution of nitrogen implanted into the above-described diffusion layer showed that as illustrated in FIG. 13, the nitrogen concentration distribution in the depth direction of the diffusion layer hardly changed before and after laser irradiation under the laser irradiation conditions of the above-described example. That is, in the case of carbon dioxide gas laser irradiation in the present invention, the diffusion of nitrogen within the diffusion layer is almost negligible.

As described heretofore, according to the present invention, it is possible to obtain excellent advantages, compared with the method described in Patent Document 1. The reason for this is probably that crystal defects have been efficiently remedied by nitrogen or fluorine implantation and laser irradiation, since nitrogen or fluorine implanted into the diffusion layer is hardly redistributed by laser irradiation, as illustrated in FIGS. 10 and 13. In the case of the method described in Patent Document 1, it is probably that the efficiency of remedying crystal defects is low since the implanted element diffuses at the time of heat treatment.

While in the present example, an explanation has been made with regard to an n-channel MOS transistor, the same advantages are available also in the case of a p-channel MOS transistor.

The present invention is intended to reduce the leakage current of a pn junction formed in a silicon substrate and, therefore, elements to be formed on the silicon substrate are not limited to a MOS transistor. Accordingly, the present invention is also applicable to a semiconductor element which includes a diffusion layer in a silicon substrate in which a pn junction is formed, such as a bipolar transistor and a diode including a diffusion layer.

It is apparent that the present invention is not limited to the above embodiments, but may be modified and changed without departing from the scope and spirit of the invention.

What is claimed is:

1. A method for manufacturing a semiconductor device, comprising:
forming a diffusion layer on a silicon substrate by doping an impurity of a first conductivity type into a region of a second conductivity type opposite to said first conductivity type and performing a heat treatment;
implanting nitrogen or fluorine ions into said diffusion layer; and
irradiating carbon dioxide gas laser light to said diffusion layer after said implanting.

2. The method for manufacturing a semiconductor device according to claim 1, further comprising, forming an oxide film on said silicon substrate before said doping said impurity.

3. The method for manufacturing a semiconductor device according to claim 1, wherein said irradiating carbon dioxide gas laser light is performed with said silicon substrate heated to 300 to 500° C.

4. The method for manufacturing a semiconductor device according to claim 1, wherein the dose amount of ions of said nitrogen or fluorine is within the range from 5×10¹²/cm² to 1×10¹⁴/cm².

5. The method for manufacturing a semiconductor device according to claim 1, wherein the dose amount of ions of said nitrogen or fluorine is within the range from 1×10¹³/cm² to 5×10¹³/cm².

6. The method for manufacturing a semiconductor device according to claim 1, wherein an amount of laser absorption at said silicon substrate during said irradiating carbon dioxide gas laser light is within the range from 2000 W/mm² to 4000 W/mm².

7. The method for manufacturing a semiconductor device according to claim 1, wherein said irradiating carbon dioxide gas laser light is performed by setting the temperature of said silicon substrate and the amount of laser absorption, such that said silicon substrate does not melt down.

8. The method for manufacturing a semiconductor device according to claim 1, wherein said irradiating includes irradiating carbon dioxide gas laser light to said diffusion layer and scanning an area including said diffusion layer on said silicon substrate.

9. The method for manufacturing a semiconductor device according to claim 8, wherein an irradiation area on said silicon substrate in said irradiating includes a long side length of 3 to 10 mm and a short side length of 50 to 200 μm.

10. The method for manufacturing a semiconductor device according to claim 9, wherein said scanning includes scanning said silicon substrate along a direction of said short side of said irradiation area, and
wherein said scanning includes first scanning and second scanning performed after said first scanning, and a part of an irradiation area in said second scanning overlap said irradiation area in said first scanning with said long side direction of said irradiation area.

11. A method for manufacturing a semiconductor device including a MOS transistor, comprising:
forming a gate electrode on a silicon substrate through a gate insulating film;
doping said silicon substrate with an impurity and performing a heat treatment, thereby forming a diffusion layer to serve as a source/drain on both sides of said gate electrode;
performing an ion-implantation of nitrogen or fluorine into said diffusion layer; and
irradiating carbon dioxide gas laser light to said diffusion layer after the ion-implantation.

12. A method of manufacturing a semiconductor device, comprising:
forming a first region having a first conductivity type in a semiconductor substrate;
forming a second region having a second conductivity type coupled to said first region;
implanting a predetermined ion into said second region; and
irradiating a laser light having a energy absorbed at bonds between silicon and oxygen atoms to said second region.

13. The method of manufacturing a semiconductor device according to claim 12, wherein said predetermined ion binds with a silicon atom having a dangling bond generated said irradiating in said semiconductor substrate.

14. The method of manufacturing a semiconductor device according to claim 12, wherein said predetermined ion is nitrogen or fluorine ions.

15. The method of manufacturing a semiconductor device according to claim 12, wherein said laser light is carbon dioxide gas laser.

16. The method of manufacturing a semiconductor devise according to claim 12, wherein said forming of second region is implanting of impurity to said semiconductor substrate and heating of said semiconductor substrate after said implanting.

17. The method of manufacturing a semiconductor device according to claim 12, wherein said semiconductor substrate including silicon and oxygen atoms.

18. The method of manufacturing a semiconductor device according to claim 12, further including forming a silicon oxidation film on said semiconductor substrate before said forming a second region.

19. The method of manufacturing a semiconductor device according to claim 12, wherein said irradiation is performed with said semiconductor substrate heated to 300 to 500° C.

20. The method of manufacturing a semiconductor device according to claim 12, further including, a forming a gate electrode of a MOS transistor above said semiconductor substrate before said forming of a second region, wherein said forming of second region is a forming a source or drain of said MOS transistor.
